(19) United States
(12) Patent Application Publication
(10) Pub. No.: US 2026/0319038 A1
(43) Pub. Date: Oct. 15, 2026

(54) SYSTEM AND METHOD FOR OUTGASSING MANAGEMENT FOR SEALED SYSTEMS

(71) Applicant: GE Precision Healthcare LLC, Waukesha, WI (US)

(72) Inventors: Ernst Wolfgang Stautner, Niskayuna, NY (US); Vijay Kumar Soni, Niskayuna, NY (US); Anbo Wu, Clifton Park, NY (US); Dogan Celik, Florence, SC (US); Zhenyu Zhang, Florence, SC (US)

(21) Appl. No.: 19/174,463

(22) Filed: Apr. 9, 2025

(51) Int. Cl. G01R 33/38; G01R 33/3815; H10N 60/83

(52) U.S. Cl. CPC G01R 33/3804; G01R 33/3815; H10N 60/83

(57) ABSTRACT

A superconducting machine system includes a superconducting machine that includes a composite structure. The superconducting machine system also includes a thermal shield encompassing the superconducting machine. The superconducting machine system further includes a vacuum vessel wall encompassing the thermal shield. The superconducting machine system still further includes a shroud encompassing the superconducting machine, wherein the thermal shield encompasses the shroud. The superconducting machine system also includes a mechanical vacuum pump located outside the vacuum vessel wall that is coupled to the shroud via piping, wherein the shroud and the mechanical vacuum pump are configured to capture and to remove outside the vacuum vessel wall outgassing gases released from the superconducting machine and the composite structure during a quench event.

### BACKGROUND

The subject matter disclosed herein relates to a system and a method for outgassing management for sealed systems.

Non-invasive imaging technologies allow images of the internal structures or features of a patient/object to be obtained without performing an invasive procedure on the patient/object. In particular, such non-invasive imaging technologies rely on various physical principles (such as the differential transmission of X-rays through a target volume, the reflection of acoustic waves within the volume, the paramagnetic properties of different tissues and materials within the volume, the breakdown of targeted radionuclides within the body, and so forth) to acquire data and to construct images or otherwise represent the observed internal features of the patient/object.

During magnetic resonance imaging (MRI), when a substance such as human tissue is subjected to a uniform magnetic field (polarizing field B₀), the individual magnetic moments of the spins in the tissue attempt to align with this polarizing field, but precess about it in random order at their characteristic Larmor frequency. If the substance, or tissue, is subjected to a magnetic field (excitation field B1) which is in the x-y plane and which is near the Larmor frequency, the net aligned moment, or “longitudinal magnetization”, M_{z}, may be rotated, or “tipped”, into the x-y plane to produce a net transverse magnetic moment, Mₜ. A signal is emitted by the excited spins after the excitation signal B₁ is terminated and this signal may be received and processed to form an image.

When utilizing these signals to produce images, magnetic field gradients (Gₓ, G_{y}, and G_{z}) are employed. Typically, the region to be imaged is scanned by a sequence of measurement cycles in which these gradient fields vary according to the particular localization method being used. The resulting set of received nuclear magnetic resonance (NMR) signals are digitized and processed to reconstruct the image using one of many well-known reconstruction techniques.

Next generation MRI magnet systems are “sealed” with coil support structures made of light weight composite materials. “Sealed” means, those MRI systems come with a reduced cryogen volume of about 5 to 40 liters compared to “wet” systems that utilize 1500 liters or more. “Sealed” systems generally leave the main magnet support structure exposed to a surrounding vacuum environment whereas with “wet” systems the magnet sits in a bath of liquid helium (i.e., bath-cooled magnet). Initially, the cryostat needs to be evacuated. The cryostat magnet coils then need to cool down to cryogenic temperatures to allow the magnet to achieve its superconducting state. After the magnet ramps to full design current, the superconducting switch is closed, and the superconducting magnet moves into a persistent state. To maintain the cryogenic temperature for the magnet a cryocooler is used. Any cryocooler may fail for many different reasons, or the cryocooler may stop due to a power outage. Even other events, like the sudden loss of vacuum or any accidents leading to the use of an emergency run down unit will make the magnet lose its superconducting state. During this event, the magnet may quench and warm up to 90 Kelvin or higher, releasing deposited gases or embedded gases, poisoning the surrounding vacuum chamber, hereby softening the vacuum. In this case, the magnet coils will therefore warm up quickly. As a result, cooldown back to the operating temperature is compromised and takes much longer. In that case, an external cooldown tool needs to be used to start precooling again which causes long delays at the site of the system.

A summary of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects that may not be set forth below.

In one embodiment, a superconducting machine system is provided. The superconducting machine system includes a superconducting machine that includes a composite structure. The superconducting machine system also includes a thermal shield encompassing the superconducting machine. The superconducting machine system further includes a vacuum vessel wall encompassing the thermal shield. The superconducting machine system still further includes a shroud encompassing the superconducting machine, wherein the thermal shield encompasses the shroud. The superconducting machine system also includes a mechanical vacuum pump located outside the vacuum vessel wall that is coupled to the shroud via piping, wherein the shroud and the mechanical vacuum pump are configured to capture and to remove outside the vacuum vessel wall outgassing gases released from the superconducting machine and the composite structure during a quench event.

In another embodiment, a superconducting magnet system for a magnetic resonance imaging system is included. The superconducting magnet system includes a superconducting magnet coil disposed on a support structure, wherein the support structure includes a composite material. The superconducting magnet system also includes a thermal shield encompassing the superconducting magnet coil and the support structure. The superconducting magnet system further includes a vacuum vessel wall encompassing the thermal shield. The superconducting magnet system even further includes a shroud encompassing the superconducting magnet coil and the support structure, wherein the thermal shield encompasses the shroud. The superconducting magnet system also includes a mechanical vacuum pump located outside the vacuum vessel wall that is coupled to the shroud via piping, wherein the shroud and the mechanical vacuum pump are configured to capture and to remove outside the vacuum vessel wall outgassing gases released from the superconducting magnet coil and the support structure during a quench event.

In a further embodiment, a method for managing outgassing from a superconducting machine system is provided. The superconducting machine system includes a superconducting machine including a composite structure. The superconducting machine system also includes a thermal shield encompassing the superconducting machine. The superconducting machine system further includes a vacuum vessel wall encompassing the thermal shield. The superconducting machine system even further includes a shroud encompassing the superconducting machine, wherein the thermal shield encompasses the shroud. The superconducting machine system also includes a mechanical vacuum pump located outside the vacuum vessel wall that is coupled to the shroud via piping. The superconducting machine system further includes a valve disposed along the piping between the vacuum vessel wall and the mechanical vacuum pump. The superconducting machine system even further includes a sorption material disposed within the shroud and/or the piping. Upon a quench event occurring to the superconducting machine system, the method includes initially capturing outgassing gases released from the superconducting machine and the composite structure during the quench event. The method also includes opening the valve when a temperature within the thermal shield is equal to or greater than a preset temperature threshold so that the mechanical vacuum pump can remove the outgassing gases from within the shroud and subsequently released from the sorption material to outside the vacuum vessel wall. The method further includes closing the valve when the temperature within the thermal shield is less than the preset temperature threshold. The method even further includes upon closing the valve, utilizing a cryocooler to cool the superconducting machine to an operating temperature.

### BRIEF DESCRIPTION OF THE DRAWINGS

These and other features, aspects, and advantages of the present disclosure will become better understood when the following detailed description is read with reference to the accompanying drawings in which like characters represent like parts throughout the drawings, wherein:

FIG. 1 is side, cross-sectional view of a cooling system for a magnetic resonance imaging machine, in accordance with aspects of the present disclosure;

FIG. 2 is a schematic illustration of the system of FIG. 1, shown in connection with a magnetic resonance imaging machine, in accordance with aspects of the present disclosure;

FIG. 3 is a schematic diagram of a cryogenic outgassing management system, in accordance with aspects of the present disclosure;

FIG. 4 is a schematic diagram of a cryogenic outgassing management integrated with a superconducting machine system (e.g., having a superconducting machine having a composite structure), in accordance with aspects of the present disclosure;

FIG. 5 is a schematic diagram of a cryogenic outgassing management integrated with a device having a composite structure, in accordance with aspects of the present disclosure;

FIG. 6 is a cross-sectional perspective view of a shroud of the cryogenic outgassing management system in FIG. 3, in accordance with aspects of the present disclosure;

FIG. 7 is a cross-sectional view of a superconducting magnet system having the cryogenic outgassing management system (e.g., lacking sorption material within a shroud and piping), in accordance with aspects of the present disclosure;

FIG. 8 is a cross-sectional view of a superconducting magnet system having the cryogenic outgassing management system (e.g., having sorption material within the shroud), in accordance with aspects of the present disclosure;

FIG. 9 is a cross-sectional view of a superconducting magnet system having the cryogenic outgassing management system (e.g., having sorption material within the piping), in accordance with aspects of the present disclosure;

FIG. 10 is a cross-sectional view of a superconducting magnet system having the cryogenic outgassing management system (e.g., having sorption material within both the shroud and the piping), in accordance with aspects of the present disclosure; and

FIG. 11 is a flow chart of a method for managing outgassing from a superconducting machine system, in accordance with aspects of the present disclosure.

### DETAILED DESCRIPTION

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers’ specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present subject matter, the articles “a,” “an,” “the,” and “said” are intended to mean that there are one or more of the elements. The terms “comprising,” “including,” and “having” are intended to be inclusive and mean that there may be additional elements other than the listed elements. Furthermore, any numerical examples in the following discussion are intended to be non-limiting, and thus additional numerical values, ranges, and percentages are within the scope of the disclosed embodiments.

While aspects of the following discussion are provided in the context of medical imaging, it should be appreciated that the disclosed techniques are not limited to such medical contexts. Indeed, the provision of examples and explanations in such a medical context is only to facilitate explanation by providing instances of real-world implementations and applications. However, the disclosed techniques may also be utilized in other contexts, such as power generation using superconducting machines. In general, the technique can be used in all superconducting machinery and/or devices (e.g., composite-based liquid hydrogen tanks) that utilize a composite structure.

The present disclosure provides a system and a method for outgassing management for sealed systems (or vacuum management in cryogenic composite environment or maintenance of cryostat vacuum integrity with composite superconducting coils). The disclosed system and method apply to any superconducting machine (e.g., superconducting electrical machine) or device that utilizes composite material (which are materials that outgas the most) for a lightweight design (e.g., superconducting magnet of a magnetic resonance imaging system, superconducting motor, superconducting generator, some composite cryostats, composite liquid hydrogen tanks for aircraft, etc.). The disclosed system and method enable avoiding the use of external cooldown tools in a quench event so that one or more cryocoolers themselves only can run the superconducting machine (e.g., magnet) back to operating temperature. The disclosed system and method avoid the softening of the vacuum chamber by enabling the capture (and release) of gases that position (e.g., contaminate) the vacuum.

In particular, the superconducting machine (e.g., magnet) and its support structure (e.g., made of composite material) is shrouded to capture outgassing gases released from the superconducting machine surface and support structure. This is particularly important for any sealed MRI system since those are built to be lightweight and are based on the use of composite material (e.g., for the former which serves as the support structure). In the absence of capturing, confining, adsorbing, containing, and removing outgassing gases that occur during a quench event, the magnet will quickly warm up to room temperature. The disclosed system and method remove the outgassing gases to outside to the vacuum vessel wall via a pump coupled to the shroud via piping. The disclosed systems and methods also provide sorption material (e.g., activated carbon advanced zeolites) disposed within the shroud and/or the piping that is configured to initially capture the outgassing gases. The disclosed systems and methods by avoiding poisoning of the vacuum reduce the time needed to return the magnet of the MRI system to an operating state from a couple of weeks down to a day in the case of MRI magnet fault condition, thus, significantly reducing MRI system downtime.

The disclosed embodiments include a superconducting machine system that includes a superconducting machine that includes a composite structure. The superconducting machine system also includes a thermal shield encompassing the superconducting machine. The superconducting machine system further includes a vacuum vessel wall encompassing the thermal shield. The superconducting machine system still further includes a shroud encompassing the superconducting machine, wherein the thermal shield encompasses the shroud. The superconducting machine system also includes a mechanical vacuum pump located outside the vacuum vessel wall that is coupled to the shroud via piping, wherein the shroud and the mechanical vacuum pump are configured to capture and to remove outside the vacuum vessel wall outgassing gases released from the superconducting machine and the composite structure during a quench event.

In certain embodiments, the shroud and the mechanical vacuum pump are configured to keep the outgassing gases from contaminating a vacuum within the vacuum vessel wall. In certain embodiments, the shroud is a vacuum enclosure configured to keep the outgassing gases from flowing outside the shroud to within the vacuum vessel wall. In certain embodiments, the mechanical vacuum pump is configured to adsorb the outgassing gases.

In certain embodiments, the superconducting machine system includes a sorption material disposed within the shroud and/or the piping that is configured to initially capture the outgassing gases. In certain embodiments, the sorption material is disposed within the shroud on the superconducting machine. In certain embodiments, the sorption material is disposed on an inner wall surface of the piping. In certain embodiments, the sorption material includes activated carbon or advanced zeolites. For example, the activated carbon may be carbon loaded paper with a composite support structure.

In certain embodiments, the superconducting machine system includes a valve disposed along the piping between the vacuum vessel wall and the mechanical vacuum pump The valve is configured to be open when a temperature within the thermal shield is equal to or greater than a preset temperature threshold so that the mechanical vacuum pump can remove the outgassing gases from within the shroud to outside the vacuum vessel wall, and the valve is configured to be closed when the temperature within the thermal shield is less than the preset temperature threshold. In certain embodiments, the superconducting machine system includes a cryocooler coupled to the vacuum vessel wall, wherein the cryocooler is configured to cool the superconducting machine, and wherein, during cooldown of the superconducting machine and with the valve closed, the cryocooler is configured to cool the superconducting machine to an operating temperature.

In certain embodiments, the superconducting machine includes a superconducting magnet coil disposed on a support structure, and the support structure includes the composite structure. In certain embodiments, the shroud includes a cryogenically flexible material (e.g., thin plastic or compliant polymer).

The disclosed embodiments include a superconducting magnet system for a magnetic resonance imaging system that includes a superconducting magnet coil disposed on a support structure, wherein the support structure includes a composite material. The superconducting magnet system also includes a thermal shield encompassing the superconducting magnet coil and the support structure. The superconducting magnet system further includes a vacuum vessel wall encompassing the thermal shield. The superconducting magnet system even further includes a shroud encompassing the superconducting magnet coil and the support structure, wherein the thermal shield encompasses the shroud. The superconducting magnet system also includes a mechanical vacuum pump located outside the vacuum vessel wall that is coupled to the shroud via piping, wherein the shroud and the mechanical vacuum pump are configured to capture and to remove outside the vacuum vessel wall outgassing gases released from the superconducting magnet coil and the support structure during a quench event.

In certain embodiments, the superconducting magnet system further includes a sorption material disposed within the shroud and/or the piping that is configured to initially capture the outgassing gases. In certain embodiments, the sorption material is disposed within the shroud on the superconducting magnet coil and the support structure. In certain embodiments, the sorption material is disposed on an inner wall surface of the piping. In certain embodiments, the sorption material includes activated carbon or advanced zeolites. For example, the activated carbon may be carbon loaded paper with a composite support structure.

In certain embodiments, the superconducting magnet system further includes a valve disposed along the piping between the vacuum vessel wall and the mechanical vacuum pump, wherein the valve is configured to be open when a temperature within the thermal shield is equal to or greater than a preset temperature threshold so that the mechanical vacuum pump can remove the outgassing gases from within the shroud to outside the vacuum vessel wall, and the valve is configured to be closed when the temperature within the thermal shield is less than the preset temperature threshold. In certain embodiments, the superconducting magnet system includes a cryocooler coupled to the vacuum vessel wall, wherein the cryocooler is configured to cool the superconducting machine, and wherein, during cooldown of the superconducting machine and with the valve closed, the cryocooler is configured to cool the superconducting magnet coil to an operating temperature.

The disclosed embodiments include a method for managing outgassing from a superconducting machine system. The superconducting machine system includes a superconducting machine including a composite structure. The superconducting machine system also includes a thermal shield encompassing the superconducting machine. The superconducting machine system further includes a vacuum vessel wall encompassing the thermal shield. The superconducting machine system even further includes a shroud encompassing the superconducting machine, wherein the thermal shield encompasses the shroud. The superconducting machine system also includes a mechanical vacuum pump located outside the vacuum vessel wall that is coupled to the shroud via piping. The superconducting machine system further includes a valve disposed along the piping between the vacuum vessel wall and the mechanical vacuum pump. The superconducting machine system even further includes a sorption material disposed within the shroud and/or the piping. Upon a quench event occurring to the superconducting machine system, the method includes initially capturing outgassing gases released from the superconducting machine and the composite structure during the quench event. The method also includes opening the valve when a temperature within the thermal shield is equal to or greater than a preset temperature threshold so that the mechanical vacuum pump can remove the outgassing gases from within the shroud and subsequently released from the sorption material to outside the vacuum vessel wall. The method further includes closing the valve when the temperature within the thermal shield is less than the preset temperature threshold. The method even further includes upon closing the valve, utilizing a cryocooler to cool the superconducting machine to an operating temperature. In certain embodiments, the shroud includes a cryogenically flexible material (e.g., thin plastic or compliant polymer).

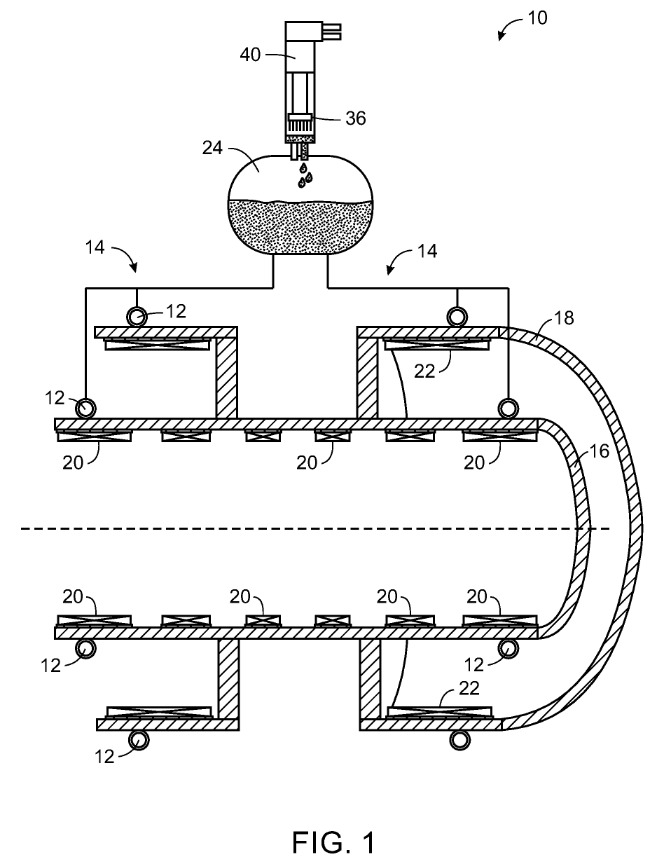

Referring now to FIG. 1, a cooling system 10 for a superconducting magnet (e.g., superconducting machine or superconducting electrical machine of a superconducting machine system) of an MRI machine (e.g., MRI system) is illustrated. As shown therein, the cooling system 10 includes a plurality of cooling tubes 12, or other suitable cooing paths, with liquid helium circulating within the cooling tubes 12. The cooling tubes 12 define a primary cooling loop 14. The cooling tubes 12 are thermally coupled to a main former or support shell 16 and, in an embodiment, may also be thermally coupled to a shield former or support shell 18 that encompasses the main former 16. The main former 16 and shield former 18 support or maintain the position of main MRI magnet coils 20 and shielding MRI magnet coils 22 (also referred to as bucking coils), respectively, in a manner heretofore known in the art. For example, the main magnet coils 20 may be shrink fit and bonded inside the main former 16, which may be a cylindrical composite former, to thereby provide thermal contact therebetween. Likewise the shield magnet coils 22 may be shrink fit and bonded inside the shield former 18, which may be a cylindrical composite former, to thereby provide thermal contact therebetween. Other types of coils may be provided, for example, epoxied coils. In an embodiment the main magnet coils 20 and the magnet shielding coils 22 may be formed from any material capable of producing a superconducting magnet, such as from Niobium-titanium (NbTi), Niobium-tin (Nb₃Sn) or Magnesium-di-boride (MgB₂) or any other type of high temperature superconductor.

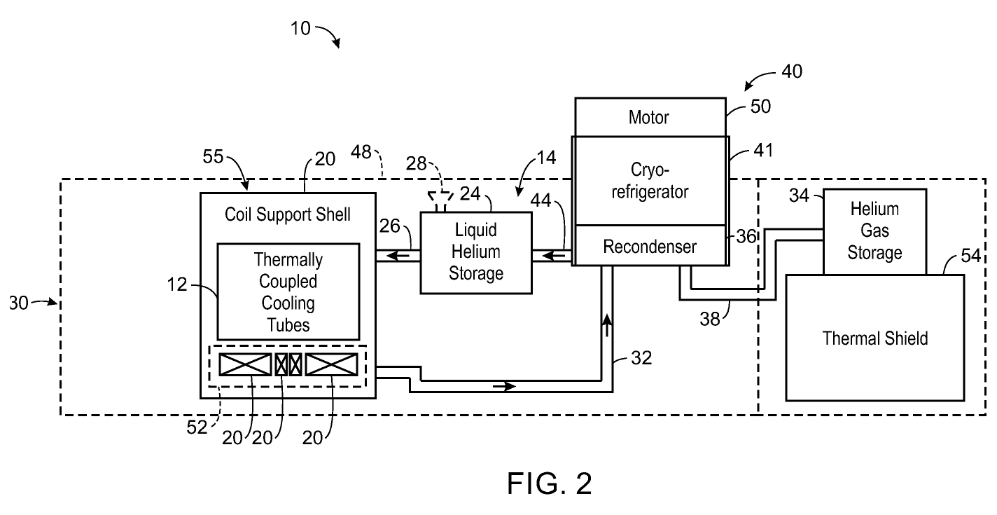

As further illustrated in FIG. 2, the various embodiments of the present invention may be implemented as part of an MRI magnet system 30, such as those commonly known in the art, wherein the cooling may be provided via a two stage cooling arrangement.

The coil formers 16, 18, which may be formed from a thermally conductive composite material, provide a cold mass support structure that maintain the position of or support the magnetic coils 20, 22, respectively (shielding magnet coils 22 not shown in FIG. 2). The coil formers 16, 18 may also be made of a composite material to make the structure lighter. The cooling tubes 12, which may be formed from any suitable metal (e.g., copper, stainless steel, aluminum, etc.) are in fluid communication with a primary, or first, liquid cryogen storage tank 24. The cryogen storage tank 24 contains a first liquid cryogen used in the closed loop cooling system 10 to cool the cold mass 55, including magnet coils 20, 22. In an embodiment, the cryogen is liquid helium. The fluid communication between the cooling tubes 12 and the liquid cryogen storage tank(s) (e.g., liquid helium storage tank(s)) 24 may be provided by one or more fluid passageways 26 (e.g., fluid tubes, conduits, etc.). Thus, the storage tank 24 provides the liquid helium that flows through the cooling tubes 12 to cool the magnet coils 20, 22.

Collectively, the assembly of magnet coils 20 and/or 22, the coil formers/support structure 16 and/or 18 and the cryogen reservoir 24 form a cold mass 55. As discussed in detail below, this cold mass 55 is cooled to target temperature. As used herein, “target temperature” means a cryogenic temperature sufficient to enable superconducting operation. In an embodiment, the target temperature is approximately 4 K. As used herein “cold mass” means any structure that is cooled to the target temperature during normal operation via the primary cooling loop 14.

In the illustrated embodiment, the primary cooling loop 14 contains no venting. However, in some embodiments, venting may be provided, for example, using a vent 28 having a very high venting pressure level. For example, in some embodiments the vent 28 is configured to provide venting at the highest pressure the system can handle without failure (or within a predefined range thereof). However, different pressure levels may be provided in embodiments that include the vent 28, which may be based on system requirements, regulatory requirements, etc.

As best illustrated in FIG. 2, in an embodiment, the cooling tubes 12 may be in fluid communication with a vapor return manifold or passageway 32, which may be in fluid communication with a helium gas storage system having a decoupled gaseous helium storage tank 34 through a recondenser 36. The helium gas storage system, which may be formed from one or more helium gas storage tanks 34 contains helium gas received as helium vapor from the cooling tubes 12 that removes heat from the magnet coils 20, 22 and forms part of the closed loop cooling system. The fluid communication between the recondenser 36 and the helium gas storage system 34 may be provided via one or more passageways 38. In certain embodiments, instead of helium, another cryogen may be utilized for cooling.

The helium gas storage tanks 34 are in fluid communication with a cryorefrigerator 40 that includes the recondenser 36, which fluid communication may be provided via one or more fluid passageways 38. In various embodiments, the recondenser 36 may draw helium gas from the helium gas storage system 34 that operates to form a free convection circulation loop to cool the magnet coils 20, 22 and coil support shells 16, 18 to a cryogenic temperature, as well as fills the reservoir 24 with liquid helium via one or more passageways 44.

The cryorefrigerator 40 (e.g., cryocooler), which may be a coldhead or other suitable cryocooler, extends through a cryostat and/or vacuum vessel 48 which contains therein the MRI magnet system 30 and the cooling components of the various embodiments. The cryorefrigerator 40 may extend within a sleeve or housing, referred to as coldhead sleeve 41. Thus, the cold end of the cryorefrigerator 40 may be positioned within the sleeve 41 without affecting the vacuum within the vacuum vessel. The cryorefrigerator 40 is inserted (or received) and secured within the sleeve using any suitable means, such as one or more flanges and bolts, or other suitable means. Moreover, a motor 50 of the cryorefrigerator 40 is provided outside the vacuum vessel and/or cryostat 48.

As illustrated in FIG. 2, the cryorefrigerator 40 in various embodiments includes the recondenser 36 at a lower end of the cryorefrigerator 40 that recondenses boiled off helium gas received from the vapor return manifold/passageway 32 in parallel with the helium gas storage system 34. The recondenser 36 allows for transferring boiled off helium gas from the helium gas storage system 34 to the liquid helium reservoir 24.

The magnet coils 20, which in various embodiments are molded coils, form a main superconducting magnet 52 that is controlled during operation of the MRI system as is known in the art to acquire MRI image data. Additionally, during operation of the MRI system, liquid helium travelling through the thermally coupled cooling tubes 12 cools the superconducting magnet 52. The superconducting magnet 52 may be cooled, for example, to a superconducting temperature, such as 4.2 Kelvin (K.). The cooling process may include the recondensing of boiled off helium gas to liquid by the recondenser 36 and returned to the liquid helium tank 24, as well as cooling of the boiled off helium.

The various embodiments also provide a thermal shield 54, which may be in thermal contact with the helium gas storage system 34. The thermal shield 54 may be, for example, a thermally isolating radiation shield.

In an embodiment, rather than cooling via the circulation of liquid helium through cooling tubes that are thermally connected to the magnet or support shell, cooling may be provided by immersing the superconducting magnet coils in a bath of liquid helium, as is known in the art. In various embodiments, once cooled to operating temperature, the magnet coils may be cooled by thermal conduction and/or by thermosiphoning cooling. As will be readily appreciated, however, whether cooling is effected through the circulation of a liquid cryogen through a cooling loop that is in thermal communication with the magnet, or through the immersion of magnet coils in a bath of liquid cryogen, the coil formers/support structure, magnet coils and/or liquid cryogen reservoir form a cold mass 55 having a temperature of approximately 4.2 K., which provides for superconducting operations. As described in greater detail below, a cryogenic outgassing management system may be provided that may be utilized in response to a quench event to minimize outgassing of the lightweight composite coil formers (and magnet) so cooldown time after the quench is minimized. In certain embodiments, outgassing management occurs in sealed, non bath-cooled systems.

Although described in the context of a superconducting magnet for an MRI system, the superconducting machine system (for which the cryogenic outgassing management system is utilized) is a superconducting generator or motor, or other type of superconducting system, such as in accelerator magnet technology, for superconducting RF cavity, or other. The cryogenic outgassing management system may also be utilized with composite cryostats, composite liquid hydrogen tanks, and other devices that utilize composite structures. The disclosed systems and methods may also be utilized with applications where a cryocooler is directly mounted onto a superconducting coil with no helium involved for cooling (i.e., conduction cooled systems or sealed systems, or completely dry systems).

It should be noted that although some embodiments may be described in connection with superconducting magnets for MRI systems, the various embodiments may be implemented in connection with any type of system having superconducting magnets. The superconducting magnets may be implemented in other types of medical imaging devices, as well as non-medical imaging devices.

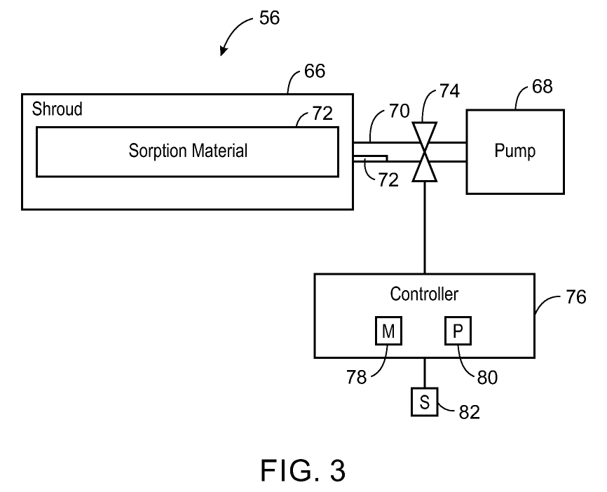

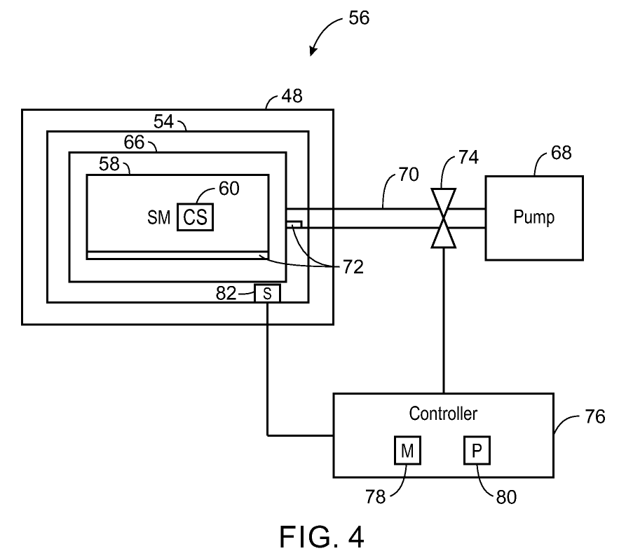

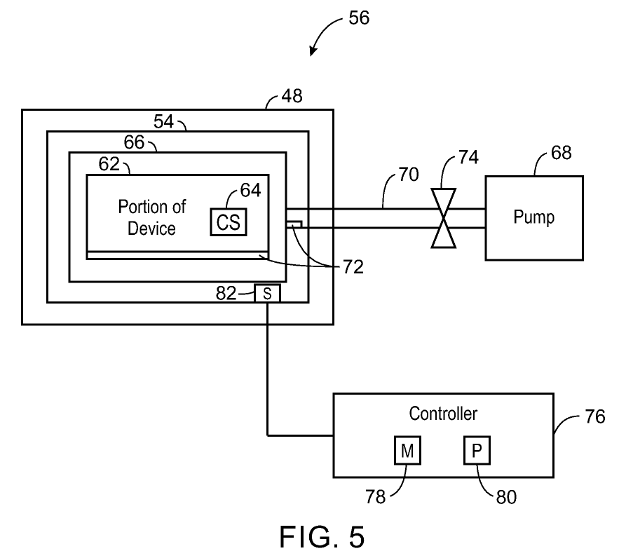

FIG. 3 is a schematic diagram of a cryogenic outgassing management system 56. The cryogenic outgassing management system 56 is configured to collect outgassing gases (e.g., N₂, O₂, H₂, Ar, long hydrocarbon chains, etc.) released from a superconducting machine 58 having a composite structure 60 (e.g., superconducting magnet, superconducting generator, etc.) as depicted in FIG. 4 or a device 62 having a composite structure 64 (e.g., composite cryostat, composite liquid hydrogen tank) as depicted in FIG. 5.

The cryogenic outgassing management system 56 includes a shroud 66 configured to be disposed within a vacuum vessel 48 and a thermal shield 54. The shroud 66 is configured to be disposed about the superconducting machine 58 and the composite structure 60 or a portion of the device 62 having the composite structure 64. The shroud 66 is configured to keep the outgassing gases (e.g., generated during a quench event) from contaminating or poisoning a vacuum within the vacuum vessel 48. The shroud 66 is a vacuum enclosure configured to keep the outgassing gases from flowing outside the shroud 66 to within the vacuum vessel 48.

The cryogenic outgassing management system 56 also includes a pump 68 (e.g., mechanical vacuum pump or sorption pump) coupled to the shroud 66 via piping 70. The pump 68 is located outside the vacuum vessel 48. The piping 70 extends from the shroud 66 to the pump 68. In certain embodiments, the pump 68 is a water jet filter pump. The pump 68 removes the outgassing gases from the shroud 66 to outside the vacuum vessel 48. In certain embodiments, the pump 68 is configured to adsorb the outgassing gases (e.g., via a sorption surface (e.g., zeolite)) (i.e., the pump 68 provides an active sorption surface).

In certain embodiments, the cryogenic outgassing management system 56 includes a sorption material 72 disposed within the shroud 66 and/or the piping 70 that is configured to initially capture the outgassing gases. Up to a certain temperature (e.g., 40 K.), the sorption material 72 captures the outgassing gases. Upon reaching that temperature, the sorption material 72 releases the outgassing gases that were captured. Thus, the sorption material 72 is configured to act as a buffer to ensure that the shroud 66 can cope with the amount of outgassing gases being released. The sorption material 72 is a passive sorption surface (i.e., room temperature activated sorption material). In certain embodiments, the sorption material 72 is activated carbon (e.g., layer of activated carbon) or advanced zeolites. For example, the activated carbon may be carbon loaded paper with a composite support structure.

In certain embodiments, the cryogenic outgassing management system 56 includes a valve 74 disposed along the flow path the piping 70 outside the vacuum vessel 48 between the pump 68 and the vacuum vessel 48. The valve 74 is configured to be open (via a control signal from a controller 76 having a memory 78 and a processor 80) when a temperature within the thermal shield 54 is equal to or greater than a preset temperature threshold so that the pump 68 can remove the outgassing gases from within the shroud 60 to outside the vacuum vessel 48. The valve 74 is configured to be closed (via a control signal from the controller 76) when the temperature within the thermal shield 54 is less than the preset temperature threshold.

The controller 76 may be communicatively coupled to one or more sensors 82 monitoring a temperature within the thermal shield 54. The controller 76 is also communicatively coupled to the valve 74. The controller 76 is configured to provide control signals to the valve 74 based on feedback (e.g., temperature measurements) received from the one or more sensors 82.

As an example, the memory 78 may store processor-executable software code or instructions (e.g., firmware or software), which are tangibly stored on a non-transitory computer readable medium. Additionally or alternatively, the memory 78 may store data. As an example, the memory 78 may include a volatile memory, such as random-access memory (RAM), and/or a nonvolatile memory, such as read-only memory (ROM), flash memory, a hard drive, or any other suitable optical, magnetic, or solid-state storage medium, or a combination thereof. Furthermore, the processor 80 may include multiple microprocessors, one or more “general-purpose” microprocessors, one or more special-purpose microprocessors, and/or one or more application specific integrated circuits (ASICS), or some combination thereof. For example, the processor 80 may include one or more reduced instruction set (RISC) or complex instruction set (CISC) processors. The processor 80 executes the software code or instructions stored in the memory 78. The processor 80 may include multiple processors, and/or the memory 78 may include multiple memory devices.

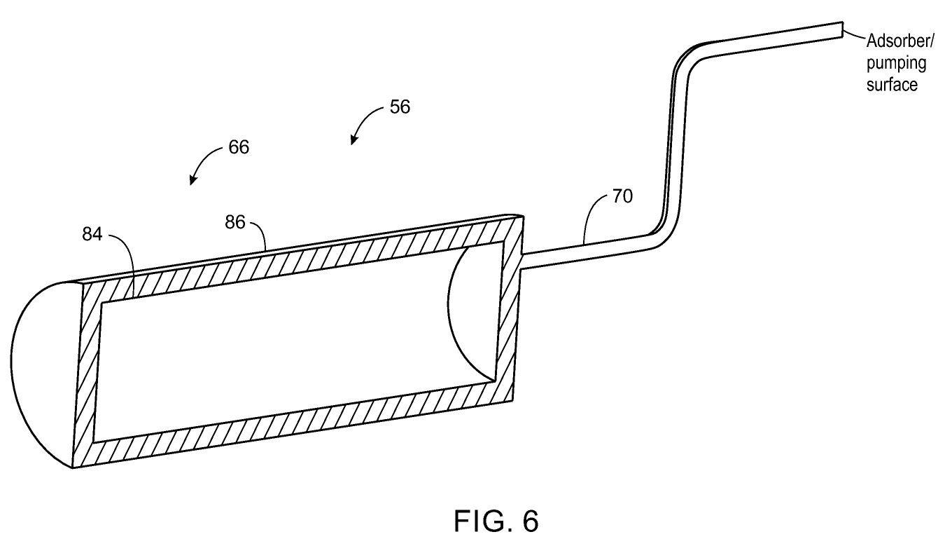

FIG. 6 is a cross-sectional perspective view of the shroud 66 of the cryogenic outgassing management system 56. The shroud 66 includes a shroud body 84. The shroud body 84 may be made of a cryogenically flexible material. In certain embodiments, the shroud body 84 may be made of thin plastic or a compliant polymer. The shroud body 84 includes a shroud covering 86. The shroud covering 86 acts as a vacuum enclosure that does not enable flow of the outgassing gases to the outer vacuum. As depicted, the shroud body 84 is coupled to the piping 70 that that provides a flow path for the outgassing gases to the adsorber/pumping surface.

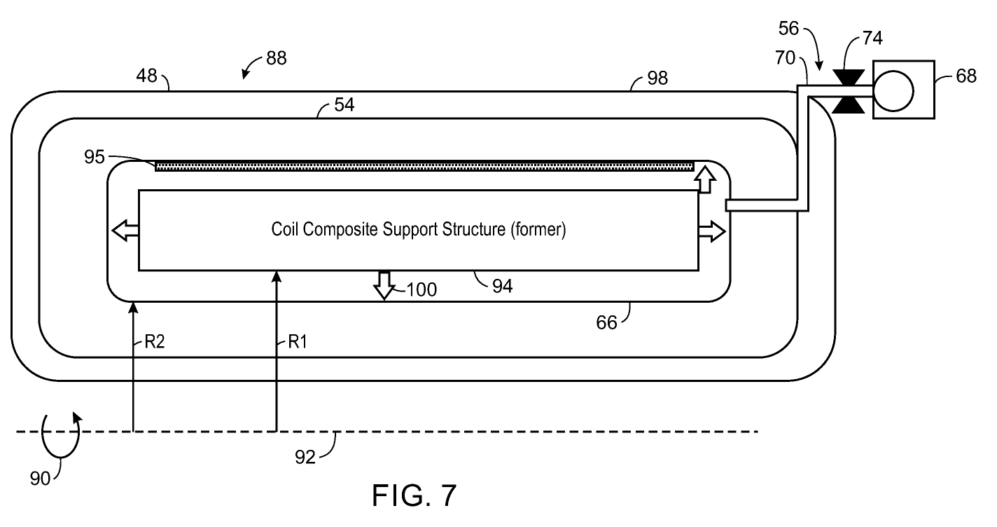

FIG. 7 is a cross-sectional view of a superconducting magnet system 88 having the cryogenic outgassing management system 56 in FIG. 3 (e.g., lacking sorption material within a shroud and piping). In certain embodiments, the superconducting magnet system 88 may be part of an MRI system. The superconducting magnet system 88 having an annular cylindrical shape extends in a circumferential direction 90 about a central axis 92.

The superconducting magnet system 88 includes a superconducting magnet coil (not shown) disposed on a coil composite support structure (e.g., former) 94. The shroud 66 of the cryogenic outgassing management system 56 encompasses the superconducting magnet coil and the coil composite support structure 94. In certain embodiments, the shroud 66 is made of a cryogenically flexible material (e.g., thin plastic or compliant polymer). The thermal shield 54 encompasses the superconducting magnet coil and the coil composite support structure 94. A vacuum vessel 48 encompasses the thermal shield 54 and the superconducting magnet coil and the coil composite support structure 94. An insulation layer 95 (e.g., 4 K. insulation layer) is disposed about the superconducting magnet coil and the coil composite support structure 94. The superconducting magnet coil and the coil composite support structure 94 has a radius R1 from the central axis 92. An inner surface 96 of the shroud 66 has a radius R2 from the central axis 92.

The pump 68 (e.g., mechanical vacuum pump or sorption pump) is located outside a wall 98 of the vacuum vessel 48. The pump 68 is coupled to the shroud 66 via the piping 70. The valve 74 is located along the piping 70 outside the wall 98 of the vacuum vessel 48 between the vacuum vessel 48 and the pump 68. Upon warming up of the magnet (e.g., during a quench event), the outgassing gases that are released (represented by arrows 100) are moving from within the shroud 66 toward the capturing device (i.e., the pump 68) within a molecular flow regime when the valve 74 is open, which enables the pump 68 to create a required pressure differential to pump out the outgassing gases from within the shroud 66.

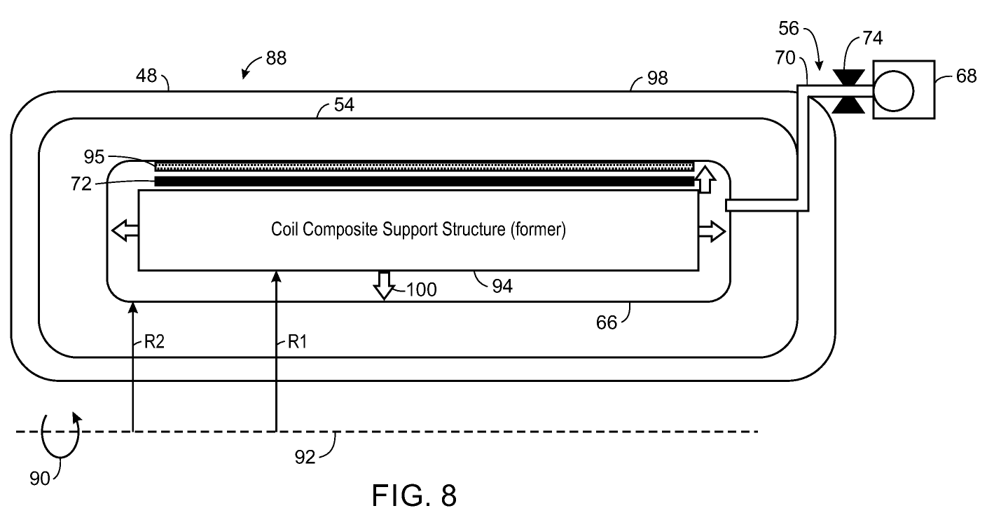

FIG. 8 is a cross-sectional view of the superconducting magnet system 88 having cryogenic outgassing management system 56 in FIG. 3 (e.g., having sorption material within the shroud). The superconducting magnet system 88 and the cryogenic outgassing management system 56 are as described in FIG. 7. In addition, the cryogenic outgassing management system 56 includes the sorption material 72 disposed within the shroud 66 that is configured to initially capture the outgassing gases. In particular, the sorption material 72 is disposed on the superconducting magnet coil and the coil composite support structure 94 between the insulation layer 95 the superconducting magnet coil and the coil composite support structure 94.

Up to a certain temperature (e.g., 40 K.), the sorption material 72 captures the outgassing gases. Upon reaching that temperature, the sorption material 72 releases the outgassing gases that were captured. Thus, the sorption material 72 is configured to act as a buffer to ensure that the shroud 66 can cope with the amount of outgassing gases being released. The sorption material 72 is a passive adsorber surface (i.e., room temperature activated sorption material). In certain embodiments, the sorption material 72 is activated carbon (e.g., layer of activated carbon) or advanced zeolites. For example, the activated carbon may be carbon loaded paper with a composite support structure.

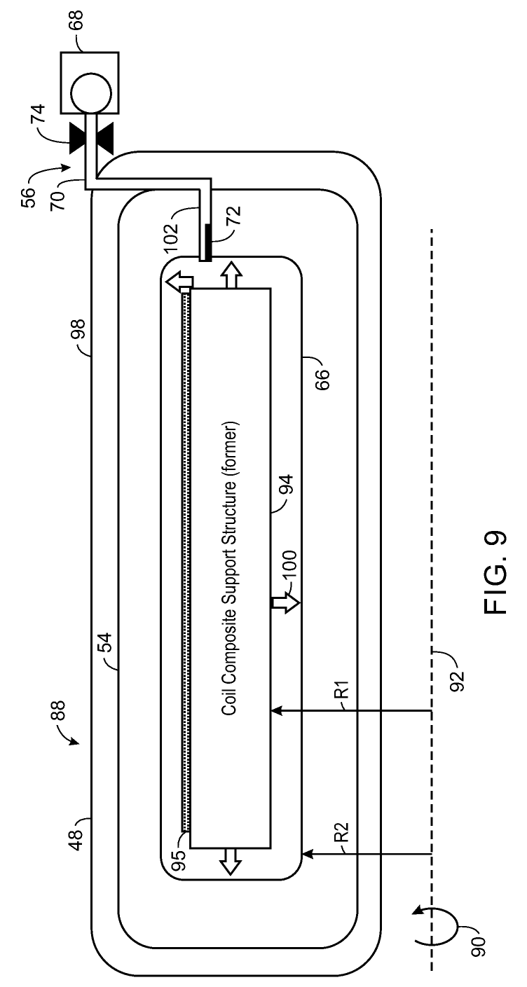

FIG. 9 is a cross-sectional view of the superconducting magnet system 88 having cryogenic outgassing management system 56 in FIG. 3 (e.g., having sorption material within the piping). The superconducting magnet system 88 and the cryogenic outgassing management system 56 are as described in FIG. 7. In addition, the cryogenic outgassing management system 56 includes the sorption material 72 disposed within the piping 70 that is configured to initially capture the outgassing gases. In particular, the sorption material 72 is disposed on an inner wall surface 102 of the piping 70. In certain embodiments, the sorption material 72 is disposed along only a portion of the inner wall surface 102 of the piping 70. In certain embodiments, the sorption material 72 is disposed along an entirety of the inner wall surface 102 of the piping 70.

Up to a certain temperature (e.g., 40 K.), the sorption material 72 captures the outgassing gases. Upon reaching that temperature, the sorption material 72 releases the outgassing gases that were captured. Thus, the sorption material 72 is configured to act as a buffer to ensure that the shroud 66 can cope with the amount of outgassing gases being released. The sorption material 72 is a passive adsorber surface (i.e., room temperature activated sorption material). In certain embodiments, the sorption material 72 is activated carbon (e.g., layer of activated carbon) or advanced zeolites. For example, the activated carbon may be carbon loaded paper with a composite support structure.

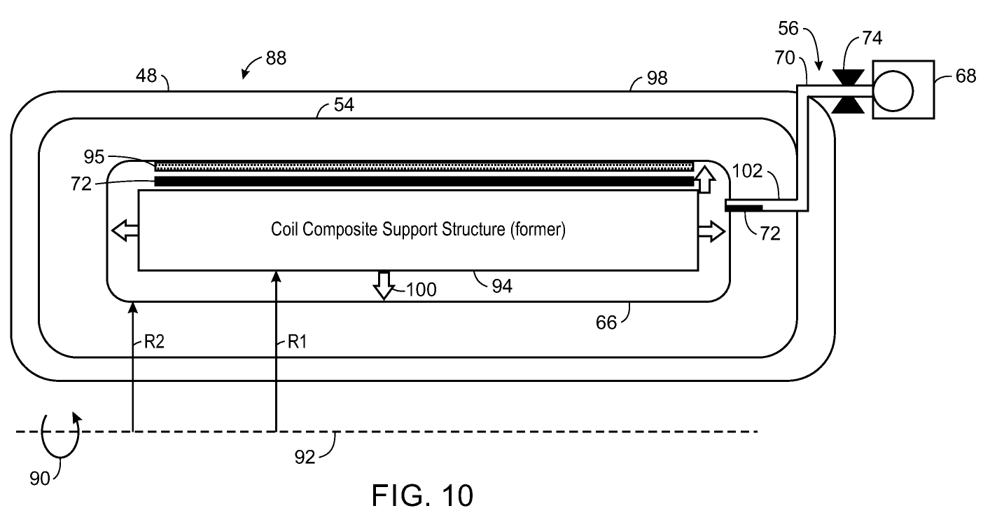

FIG. 10 is a cross-sectional view of the superconducting magnet system 88 having cryogenic outgassing management system 56 in FIG. 3 (e.g., having sorption material within both the shroud and the piping). The superconducting magnet system 88 and the cryogenic outgassing management system 56 are as described in FIG. 7. In addition, the cryogenic outgassing management system 56 includes the sorption material 72 disposed within the shroud 66 that is configured to initially capture the outgassing gases. In particular, the sorption material 72 is disposed on the superconducting magnet coil and the coil composite support structure 94 between the insulation layer 95 the superconducting magnet coil and the coil composite support structure 94. Further, the outgassing management system 56 includes the sorption material 72 disposed within the piping 70 that is configured to initially capture the outgassing gases. In particular, the sorption material 72 is disposed on an inner wall surface 102 of the piping 70. In certain embodiments, the sorption material 72 is disposed along only a portion the inner wall surface 102 of the piping 70. In certain embodiments, the sorption material 72 is disposed along an entirety of the inner wall surface 102 of the piping 70.

Up to a certain temperature (e.g., 40 K.), the sorption material 72 captures the outgassing gases. Upon reaching that temperature, the sorption material 72 releases the outgassing gases that were captured. Thus, the sorption material 72 is configured to act as a buffer to ensure that the shroud 66 can cope with the amount of outgassing gases being released. The sorption material 72 is a passive adsorber surface (i.e., room temperature activated sorption material). In certain embodiments, the sorption material 72 is activated carbon (e.g., layer of activated carbon) or advanced zeolites. For example, the activated carbon may be carbon loaded paper with a composite support structure.

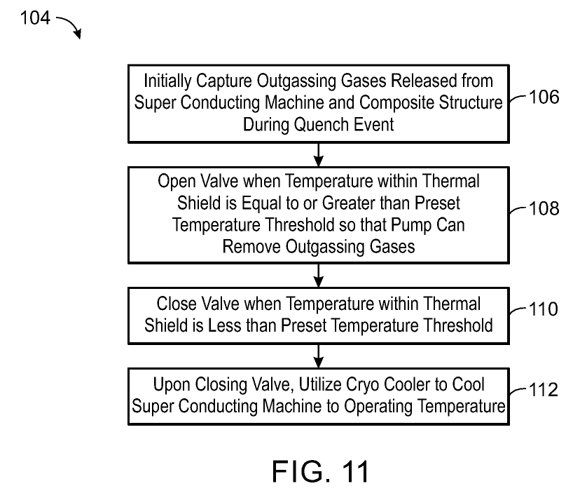

FIG. 11 is a flow chart of a method 104 for managing outgassing from a superconducting machine system (or vacuum management in cryogenic composite environment or maintenance of cryostat vacuum integrity with composite superconducting coils). The superconducting machine system includes a superconducting machine having a composite material (e.g., superconducting electrical machine such as a superconducting magnet of a magnetic resonance imaging system, a superconducting motor, a superconducting generator, etc.). A method similar to the method 104 may be utilized with a device that utilizes composite material (e.g., some composite cryostats, composite liquid hydrogen tanks for aircraft, etc.).

As described above, the superconducting machine system includes a superconducting machine including a composite structure. The superconducting machine system also includes a thermal shield encompassing the superconducting machine. The superconducting machine system further includes a vacuum vessel wall encompassing the thermal shield. The superconducting machine system even further includes a shroud encompassing the superconducting machine, wherein the thermal shield encompasses the shroud. The superconducting machine system also includes a mechanical vacuum pump located outside the vacuum vessel wall that is coupled to the shroud via piping. The superconducting machine system further includes a valve disposed along the piping between the vacuum vessel wall and the mechanical vacuum pump. The superconducting machine system even further includes a sorption material disposed within the shroud and/or the piping.

The method 104 includes initially capturing outgassing gases released from the superconducting machine and the composite structure during a quench event (block 106). The method 104 also includes opening the valve when a temperature within the thermal shield is equal to or greater than a preset temperature threshold so that the mechanical vacuum pump can remove the outgassing gases from within the shroud and subsequently released from the sorption material to outside the vacuum vessel wall (block 108). The method 104 further includes closing the valve when the temperature within the thermal shield is less than the preset temperature threshold (block 110). The method 104 even further includes, upon closing the valve, utilizing a cryocooler to cool the superconducting machine to an operating temperature (block 112).

Technical effects of the disclosed subject matter include providing for outgassing management for sealed systems (or vacuum management in cryogenic composite environment or maintenance of cryostat vacuum integrity with composite superconducting coils). Technical effects of the disclosed embodiments include enabling avoiding the use of external cooldown tools in a quench event so that one or more cryocoolers themselves only can run the superconducting machine (e.g., magnet) back to operating temperature. Technical effects of the disclosed embodiments include avoiding the softening of the vacuum chamber by enabling the capture (and release) of gases that position (e.g., contaminate) the vacuum.

The disclosure also provides support for a superconducting machine system, comprising: a superconducting machine comprising a composite structure; a thermal shield encompassing the superconducting machine; a vacuum vessel wall encompassing the thermal shield; a shroud encompassing the superconducting machine, wherein the thermal shield encompasses the shroud; and a mechanical vacuum pump located outside the vacuum vessel wall that is coupled to the shroud via piping, wherein the shroud and the mechanical vacuum pump are configured to capture and to remove outside the vacuum vessel wall outgassing gases released from the superconducting machine and the composite structure during a quench event. In a first example of the superconducting machine system, the shroud and the mechanical vacuum pump are configured to keep the outgassing gases from contaminating a vacuum within the vacuum vessel wall. In a second example of the superconducting machine system, optionally including the first example, the shroud is a vacuum enclosure configured to keep the outgassing gases from flowing outside the shroud to within the vacuum vessel wall. In a third example of the superconducting machine system, optionally including one or both of the first and second examples, the mechanical vacuum pump is configured to adsorb the outgassing gases. In a fourth example of the superconducting machine system, optionally including one or more of each of the first through third examples, the superconducting system further comprises a sorption material disposed within the shroud and/or the piping that is configured to initially capture the outgassing gases. In a fifth example of the superconducting machine system, optionally including one or more of each of the first through fourth examples, the sorption material is disposed within the shroud on the superconducting machine. In a sixth example of the superconducting machine system, optionally including one or more of each of the first through fifth examples, the sorption material is disposed on an inner wall surface of the piping. In a seventh example of the superconducting machine system, optionally including one or more of each of the first through sixth examples, the sorption material comprises activated carbon or advanced zeolites. In an eighth example of the superconducting machine system, optionally including one or more of each of the first through seventh examples, the superconducting machine system further comprises a valve disposed along the piping between the vacuum vessel wall and the mechanical vacuum pump, wherein the valve is configured to be open when a temperature within the thermal shield is equal to or greater than a preset temperature threshold so that the mechanical vacuum pump can remove the outgassing gases from within the shroud to outside the vacuum vessel wall, and the valve is configured to be closed when the temperature within the thermal shield is less than the preset temperature threshold. In a ninth example of the superconducting machine system, optionally including one or more of each of the first through eighth examples, the superconducting machine system further comprises a cryocooler coupled to the vacuum vessel wall, wherein the cryocooler is configured to cool the superconducting machine, and wherein, during cooldown of the superconducting machine and with the valve closed, the cryocooler is configured to cool the superconducting machine to an operating temperature. In a tenth example of the superconducting machine system, optionally including one or more of each of the first through ninth examples, the superconducting machine comprises a superconducting magnet coil disposed on a support structure, and the support structure comprises the composite structure. In an eleventh example of the superconducting machine system, optionally including one or more of each of the first through tenth examples, the shroud comprises a cryogenically flexible material.

The disclosure also provides support for a superconducting magnet system for a magnetic resonance imaging system, comprising: a superconducting magnet coil disposed on a support structure, wherein the support structure comprises a composite material; a thermal shield encompassing the superconducting magnet coil and the support structure; a vacuum vessel wall encompassing the thermal shield; a shroud encompassing the superconducting magnet coil and the support structure, wherein the thermal shield encompasses the shroud; and a mechanical vacuum pump located outside the vacuum vessel wall that is coupled to the shroud via piping, wherein the shroud and the mechanical vacuum pump are configured to capture and to remove outside the vacuum vessel wall outgassing gases released from the superconducting magnet coil and the support structure during a quench event. In a first example of the superconducting magnet system, the superconducting magnet system further comprises a sorption material disposed within the shroud and/or the piping that is configured to initially capture the outgassing gases. In a second example of the superconducting magnet system, optionally including the first example, the sorption material is disposed within the shroud on the superconducting magnet coil and the support structure. In a third example of the superconducting magnet system, optionally including one or both of the first and second examples, the sorption material is disposed on an inner wall surface of the piping. In a fourth example of the superconducting magnet system, optionally including one or more of each of the first through third examples, the sorption material comprises activated carbon or advanced zeolites. In a fifth example of the superconducting magnet system, optionally including one or more of each of the first through fourth examples, the superconducting magnet system further comprises a valve disposed along the piping between the vacuum vessel wall and the mechanical vacuum pump, wherein the valve is configured to be open when a temperature within the thermal shield is equal to or greater than a preset temperature threshold so that the mechanical vacuum pump can remove the outgassing gases from within the shroud to outside the vacuum vessel wall, and the valve is configured to be closed when the temperature within the thermal shield is less than the preset temperature threshold. In a sixth example of the superconducting magnet system, optionally including one or more of each of the first through fifth examples, the superconducting magnet system further comprises a cryocooler coupled to the vacuum vessel wall, wherein the cryocooler is configured to cool the superconducting machine, and wherein, during cooldown of the superconducting machine and with the valve closed, the cryocooler is configured to cool the superconducting magnet coil to an operating temperature.

The disclosure also provides support for a method for managing outgassing from a superconducting machine system, comprising: for the superconducting machine system, comprising: a superconducting machine comprising a composite structure; a thermal shield encompassing the superconducting machine; a vacuum vessel wall encompassing the thermal shield; a shroud encompassing the superconducting machine, wherein the thermal shield encompasses the shroud; a mechanical vacuum pump located outside the vacuum vessel wall that is coupled to the shroud via piping; a valve disposed along the piping between the vacuum vessel wall and the mechanical vacuum pump; and an sorption material disposed within the shroud and/or the piping; upon a quench event occurring to the superconducting machine system, the method comprises: initially capturing outgassing gases released from the superconducting machine and the composite structure during the quench event; opening the valve when a temperature within the thermal shield is equal to or greater than a preset temperature threshold so that the mechanical vacuum pump can remove the outgassing gases from within the shroud and subsequently released from the sorption material to outside the vacuum vessel wall; closing the valve when the temperature within the thermal shield is less than the preset temperature threshold; and upon closing the valve, utilizing a cryocooler to cool the superconducting machine to an operating temperature.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function]…” or “step for [perform]ing [a function]…”, it is intended that such elements are to be interpreted under 35 U.S.C. 112(f). However, for any claims containing elements designated in any other manner, it is intended that such elements are not to be interpreted under 35 U.S.C. 112(f).

This written description uses examples to disclose the present subject matter, including the best mode, and also to enable any person skilled in the art to practice the subject matter, including making and using any devices or systems and performing any incorporated methods. The patentable scope of the subject matter is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

1. A superconducting machine system, comprising:
a superconducting machine comprising a composite structure;
a thermal shield encompassing the superconducting machine;
a vacuum vessel wall encompassing the thermal shield;
a shroud encompassing the superconducting machine, wherein the thermal shield encompasses the shroud; and
a mechanical vacuum pump located outside the vacuum vessel wall that is coupled to the shroud via piping, wherein the shroud and the mechanical vacuum pump are configured to capture and to remove outside the vacuum vessel wall outgassing gases released from the superconducting machine and the composite structure during a quench event.

2. The superconducting machine system of claim 1, wherein the shroud and the mechanical vacuum pump are configured to keep the outgassing gases from contaminating a vacuum within the vacuum vessel wall.

3. The superconducting machine system of claim 1, wherein the shroud is a vacuum enclosure configured to keep the outgassing gases from flowing outside the shroud to within the vacuum vessel wall.

4. The superconducting machine system of claim 1, wherein the mechanical vacuum pump is configured to adsorb the outgassing gases.

5. The superconducting machine system of claim 1, further comprising a sorption material disposed within the shroud and/or the piping that is configured to initially capture the outgassing gases.

6. The superconducting machine system of claim 5, wherein the sorption material is disposed within the shroud on the superconducting machine.

7. The superconducting machine system of claim 5, wherein the sorption material is disposed on an inner wall surface of the piping.

8. The superconducting machine system of claim 5, wherein the sorption material comprises activated carbon or advanced zeolites.

9. The superconducting machine system of claim 1, further comprising a valve disposed along the piping between the vacuum vessel wall and the mechanical vacuum pump, wherein the valve is configured to be open when a temperature within the thermal shield is equal to or greater than a preset temperature threshold so that the mechanical vacuum pump can remove the outgassing gases from within the shroud to outside the vacuum vessel wall, and the valve is configured to be closed when the temperature within the thermal shield is less than the preset temperature threshold.

10. The superconducting machine system of claim 9, further comprising a cryocooler coupled to the vacuum vessel wall, wherein the cryocooler is configured to cool the superconducting machine, and wherein, during cooldown of the superconducting machine and with the valve closed, the cryocooler is configured to cool the superconducting machine to an operating temperature.

11. The superconducting machine system of claim 1, wherein the superconducting machine comprises a superconducting magnet coil disposed on a support structure, and the support structure comprises the composite structure.

12. The superconducting machine system of claim 1, wherein the shroud comprises a cryogenically flexible material.

13. A superconducting magnet system for a magnetic resonance imaging system, comprising:
a superconducting magnet coil disposed on a support structure, wherein the support structure comprises a composite material;
a thermal shield encompassing the superconducting magnet coil and the support structure;
a vacuum vessel wall encompassing the thermal shield;
a shroud encompassing the superconducting magnet coil and the support structure, wherein the thermal shield encompasses the shroud; and
a mechanical vacuum pump located outside the vacuum vessel wall that is coupled to the shroud via piping, wherein the shroud and the mechanical vacuum pump are configured to capture and to remove outside the vacuum vessel wall outgassing gases released from the superconducting magnet coil and the support structure during a quench event.

14. The superconducting magnet system of claim 13, further comprising a sorption material disposed within the shroud and/or the piping that is configured to initially capture the outgassing gases.

15. The superconducting magnet system of claim 14, wherein the sorption material is disposed within the shroud on the superconducting magnet coil and the support structure.

16. The superconducting magnet system of claim 14, wherein the sorption material is disposed on an inner wall surface of the piping.

17. The superconducting magnet system of claim 14, wherein the sorption material comprises activated carbon or advanced zeolites.

18. The superconducting magnet system of claim 13, further comprising a valve disposed along the piping between the vacuum vessel wall and the mechanical vacuum pump, wherein the valve is configured to be open when a temperature within the thermal shield is equal to or greater than a preset temperature threshold so that the mechanical vacuum pump can remove the outgassing gases from within the shroud to outside the vacuum vessel wall, and the valve is configured to be closed when the temperature within the thermal shield is less than the preset temperature threshold.

19. The superconducting magnet system of claim 18, further comprising a cryocooler coupled to the vacuum vessel wall, wherein the cryocooler is configured to cool the superconducting machine, and wherein, during cooldown of the superconducting machine and with the valve closed, the cryocooler is configured to cool the superconducting magnet coil to an operating temperature.

20. A method for managing outgassing from a superconducting machine system, comprising:
for the superconducting machine system, comprising:
a superconducting machine comprising a composite structure;
a thermal shield encompassing the superconducting machine;
a vacuum vessel wall encompassing the thermal shield;
a shroud encompassing the superconducting machine, wherein the thermal shield encompasses the shroud;
a mechanical vacuum pump located outside the vacuum vessel wall that is coupled to the shroud via piping;
a valve disposed along the piping between the vacuum vessel wall and the mechanical vacuum pump; and
a sorption material disposed within the shroud and/or the piping;
upon a quench event occurring to the superconducting machine system, the method comprises:
initially capturing outgassing gases released from the superconducting machine and the composite structure during the quench event;
opening the valve when a temperature within the thermal shield is equal to or greater than a preset temperature threshold so that the mechanical vacuum pump can remove the outgassing gases from within the shroud and subsequently released from the sorption material to outside the vacuum vessel wall;
closing the valve when the temperature within the thermal shield is less than the preset temperature threshold; and
upon closing the valve, utilizing a cryocooler to cool the superconducting machine to an operating temperature.
